(19) United States
(12) Patent Application Publication
(10) Pub. No.: US 2017/0192366 A1
(43) Pub. Date: Jul. 6, 2017

(54) DEVICE AND METHOD FOR CLEANING MASK PLATE AND VAPOR DEPOSITION APPARATUS

(71) Applicants: BOE TECHNOLOGY GROUP CO., LTD., Beijing (CN); ORDOS YUANSHENG OPTOELECTRONICS CO., LTD., Ordos (CN)

(72) Inventors: Qiang WANG, Beijing (CN); Libin LIU, Beijing (CN)

(73) Assignees: BOE TECHNOLOGY GROUP CO., LTD., Beijing (CN); ORDOS YUANSHENG OPTOELECTRONICS CO., LTD., Ordos (CN)

(21) Appl. No.: 15/198,121

(22) Filed: Jun. 30, 2016

(30) Foreign Application Priority Data
Jan. 4, 2016 (CN) 201610005888.7

(51) Int. Cl. G03F 7/20

(52) U.S. Cl. CPC G03F 7/70925; G03F 7/70866

(57) ABSTRACT

A device for cleaning a mask plate includes an oscillation unit. The oscillation unit is on the mask plate. After completion of vapor deposition with the mask plate, the oscillation unit applies vibration force to the mask plate in a manner of causing residual material on the mask plate to fall off.

### CROSS REFERENCE OF RELATED APPLICATION

The present application claims a priority of the Chinese patent application No. 201610005888.7 filed on Jan. 4, 2016, which is incorporated herein by reference in its entirety.

### TECHNICAL FIELD

The present disclosure relates to the field of display technologies, in particular to a device and method for cleaning mask plates and a vapor deposition apparatus.

### BACKGROUND

When a vapor deposition operation is carried out by a vapor deposition apparatus on a component such as a substrate, a fine metal mask (FMM) is usually to control a pattern to be formed by depositing evaporation membrane material on the component such as the substrate.

In mass production, one piece of FMM is needed to be reused many times. In order to avoid pollution and color mixture, it is needed to clean the FMM after each use of the FMM.

In the related art, generally, there are two methods for cleaning the FMM. For example, one is to heat the entire FMM to evaporate residual organic material away from the FMM; and another one is to clean the FMM with organic solvent, i.e., selecting different organic solvents for different organic materials so as to obtain the maximum solubility, and then removing residual organic material on the FMM by immersing the FMM in the organic solvent.

However, in the above two methods, when the entire FMM is heated, the FMM may be heated to a high temperature and expand, and then the FMM may be damaged; when the FMM is cleaned with the organic solvent, the process is complicated, and a large amount of organic solvent is required for each time, which easily results in waste of resources and environment pollution.

### SUMMARY

The technical problem to be solved by the present disclosure is the problem of damage of mask plates, waste of resources and environment pollution in the methods of the related art such as cleaning with organic solvent or high temperature.

In order to solve the above technical problem, the present disclosure provides a device for cleaning a mask plate, which includes an oscillation unit. The oscillation unit is on the mask plate; after completion of vapor deposition with the mask plate, the oscillation unit applies vibration force to the mask plate in a manner of causing residual material on the mask plate to fall off.

Further, the device further includes an electrostatic adsorption unit. The electrostatic adsorption unit generates static electricity to adsorb the residual material on the mask plate.

Further, the device further includes a recovery unit. The recovery unit is configured to collect the residual material fallen off from the mask plate.

Further, the electrostatic adsorption unit includes a power supply and electrode clamps. The electrode clamps are clamped to the mask plate and in electrical connection with the power supply. The recovery unit is in electrical connection with the power supply; the power supply applies a voltage between the recovery unit and the mask plate to produce an electrostatic adsorption force.

Further, the electrode clamps are clamped to corners of the mask plate, respectively.

Further, the oscillation unit is an ultrasonic oscillator; the ultrasonic oscillator is at a lateral side of the mask plate.

Further, the mask plate is a metal mask plate.

The present disclosure further provides a vapor deposition apparatus, which includes a mask plate and a device for cleaning the mask plate. The device includes an oscillation unit on the mask plate.

Further, the oscillation unit includes an ultrasonic oscillator.

Further, the ultrasonic oscillator is at a lateral side of the mask plate.

Further, the vapor deposition apparatus includes a vapor deposition chamber, a substrate with a back circuit and a crucible. The substrate and the crucible are in the vapor deposition chamber, and the mask plate is between the substrate and the crucible.

Further, the vapor deposition apparatus includes an electrostatic adsorption unit. The electrostatic adsorption unit faces evaporation membrane material deposited on the mask plate.

Further, the vapor deposition apparatus includes a recovery unit. The recovery unit is in electrical connection with the electrostatic adsorption unit.

Further, the electrostatic adsorption unit includes a power supply and electrode clamps; the electrode clamps are clamped to the mask plate and in electrical connection with the power supply; the recovery unit is in electrical connection with the power supply.

Further, the electrode clamps are clamped to corners of the mask plate.

The present disclosure further provides a method for cleaning a mask plate, which include: after completion of vapor deposition with the mask plate, applying vibration force to the mask plate by adjusting vibration intensities and frequencies of oscillation units to cause residual material on the mask plate to fall off.

Further, before, after or simultaneously with applying vibration force to the mask plate by adjusting vibration intensities and frequencies of the oscillation units, the method further includes: applying a voltage between a recovery unit and the mask plate through an electrostatic adsorption unit so as to produce an electrostatic adsorption force, to accelerate a speed at which the residual organic material falls off from the mask plate to the recovery unit under effect of the electrostatic adsorption force and the gravity.

The above technical solution has at least following beneficial effects. The device for cleaning mask plates of the present disclosure achieves cleaning of the organic light emitting material according to the ultrasonic vibration principle, and can effectively avoid the problems of damage of the mask plate, waste of resources and environment pollution in the methods of the related art such as cleaning with organic solvent or high temperature. In addition, by cleaning the mask plate through oscillating the mask plate, it is able to avoid introduction of external contamination, reuse recycled material, greatly save time and resource costs, and is suitable for green production and mass production.

### BRIEF DESCRIPTION OF THE DRAWINGS

FIG. 1 is a schematic view of a vapor deposition apparatus in the related art;

FIG. 2 is a schematic view showing formation of solid organic light emitting material on a substrate and a mask plate via the vapor deposition apparatus in the related art;

FIG. 3 is a schematic view of a device for cleaning mask plates according to some embodiments of the present disclosure;

FIG. 4 is a top view of the device for cleaning mask plates according to some embodiments of the present disclosure;

FIG. 5 is a schematic view of a mask plate before being cleaned;

FIG. 6 is a schematic view of the mask plate after being cleaned according to some embodiments of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments are merely a part of, rather than all of, the embodiments of the present disclosure, and based on these embodiments, a person skilled in the art may obtain the other embodiments, which also fall within the scope of the present disclosure.

Unless otherwise defined, any technical or scientific terms used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than being limited to physical or mechanical connection. Such words as “on/above”, “under/below”, “left” and “right” are merely used to represent relative position relationship, and when an absolute position of an object is changed, the relative position relationship will be changed too.

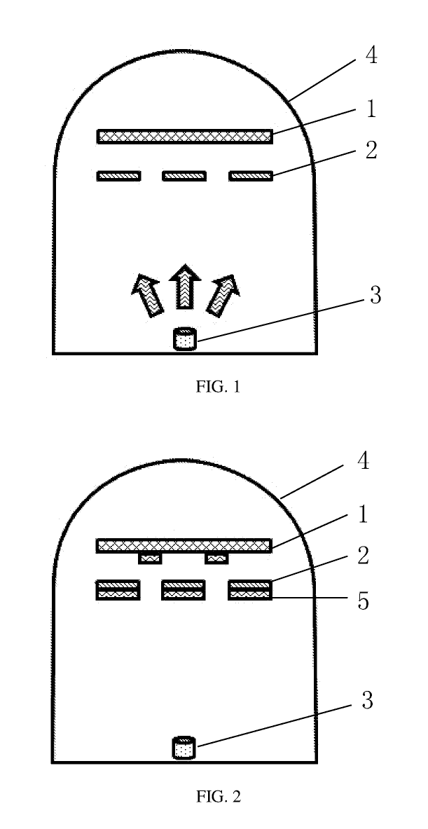

As shown in FIG. 1, a vapor deposition apparatus in the related art generally includes a substrate 1 which is provided with a back circuit, a fine metal mask (FMM) 2, a crucible 3 and a vapor deposition chamber 4. During a vapor deposition process, as shown in FIG. 2, the crucible 3 is heated to a high temperature, and organic light emitting material 5 is evaporated and deposited on the substrate 1 and the FMM 2, thereby forming solid organic light emitting material 5.

In mass production, one piece of FMM is needed to be reused many times. In order to avoid pollution and color mixture, it is needed to clean the FMM after each use of the FMM.

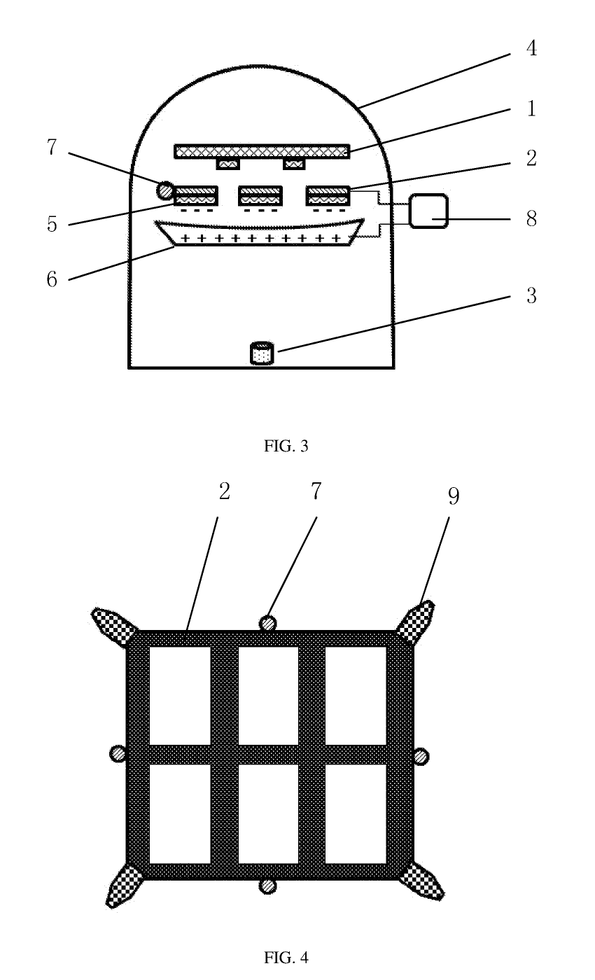

The present disclosure provides in some embodiments a device for cleaning mask plates. As shown in FIG. 3, the device for cleaning mask plates includes an oscillation unit 7. The oscillation unit 7 is on the mask plate 2. After completion of vapor deposition with the mask plate 2 (e.g., after organic light emitting material is evaporated and then deposited on the substrate 1 and the mask plate), the oscillation unit 7 applies vibration force to the mask plate 2, so as to cause residual material on the mask plate 2 to fall off. The mask plate 2 may be a fine metal mask (FMM).

As can be seen, the device for cleaning mask plates of one embodiment of the present disclosure can effectively avoid the problems of damage of the mask plate 2, waste of resources and environment pollution in the methods of the related art such as cleaning with organic solvent or high temperature. In addition, by cleaning the mask plate through oscillating the mask plate, it is able to avoid introduction of external contamination, reuse recycled material, greatly save time and resource costs, and is suitable for green production and mass production.

In order to achieve better cleaning effect, as shown in FIGS. 3-4, the device for cleaning mask plates of one embodiment further includes an electrostatic adsorption unit. The electrostatic adsorption unit generates static electricity to adsorb residual material on the mask plate 2. The electrostatic adsorption unit may cooperate with the oscillation unit 7, so as to cause the residual material on the mask plate 2 to fall off under the effect of both of the electrostatic force and the gravity, thereby further improving cleaning effect.

In addition, the device for cleaning mask plates further includes a recovery unit 6. The recovery unit 6 is below the mask plate 2, and is configured to collect the residual material fallen off from the mask plate 2. The organic material collected in the recovery unit 6 can be reused, thereby improving material utilization.

In one embodiment, the electrostatic adsorption unit may cooperate with the recovery unit 6 in a manner of applying a voltage between the recovery unit 6 and the mask plate 2 so as to produce an electrostatic adsorption force. Specifically, the electrostatic adsorption unit includes a power supply 8 and electrode clamps 9. The electrode clamps 9 are clamped to the mask plate 2 and in electrical connection with the power supply 8. The recovery unit 6 is in electrical connection with the power supply 8. The power supply 8 applies a voltage between the recovery unit 6 and the mask plate 2 to produce an electrostatic adsorption force. Under the effect of both of the electrostatic adsorption force and the gravity, it is able to accelerate the speed at which the residual organic material falls off from the mask plate, thereby greatly improving cleaning effect.

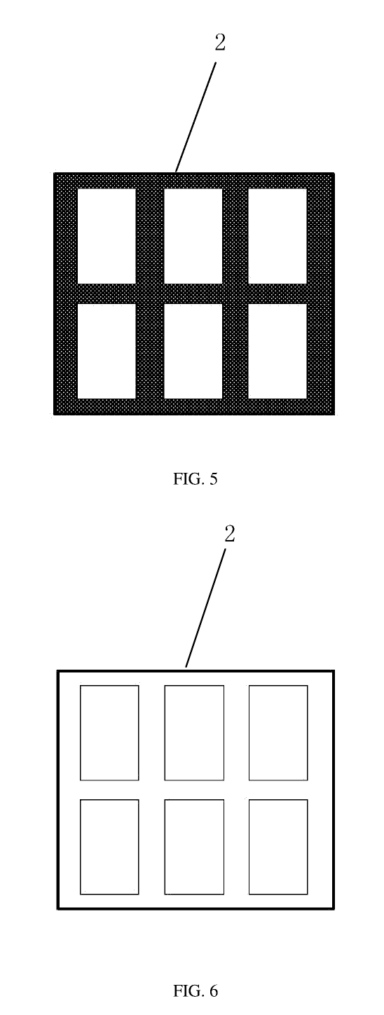

Detailed structures of the device for cleaning mask plates will be described with following examples. The device for cleaning mask plates may clean fine metal masks. FIG. 5 is a schematic view showing a mask plate before being cleaned, and FIG. 6 is a schematic view showing the mask plate after being cleaned. In addition, after completion of cleaning of the mask plate, the recycled material may be reused, thereby greatly saving time and resource costs.

Optionally, the oscillation unit 7 may employ an ultrasonic oscillator. The ultrasonic oscillator may be provided at a lateral side of the mask plate 2. In one embodiment, each lateral side of the mask plate 2 is provided with one ultrasonic oscillator. By adjusting vibration intensities of different ultrasonic oscillators, the residual material on the mask plate 2 may be removed with different priorities. As can be seen, the ultrasonic oscillators provide vibration energy for the mask plate 2, and it is able to adjust the speed at which the organic material falls off from the mask plate by adjusting vibration intensities and frequencies of the ultrasonic oscillators. It should be noted, when adjusting the frequencies of the ultrasonic oscillators, it is needed to avoid the natural frequency of the mask plate 2, so as to prevent resonance which may damage the mask plate 2.

Meanwhile, the power supply 8 may employ a multi-channel power supply to apply positive and negative voltages to the recovery unit 6 and the mask plate 2 so as to produce an electrostatic adsorption force between the recovery unit 6 and the mask plate 2. The electrode clamps 9 may be clamped to corners of the mask plate 2, i.e., providing one electrode clamp at each of four corners of the mask plate 2, thereby avoiding voltage drop caused by load resistance of the mask plate and achieving voltage compensation. In addition, it is able to change electrostatic adsorption strengths of different regions with different priorities by adjusting sizes of electrode voltages.

The present disclosure provides in some embodiments a vapor deposition apparatus, which includes the above device for cleaning mask plates. The device for cleaning mask plates includes an oscillation unit 7. The oscillation unit 7 is on the mask plate 2. After completion of vapor deposition with the mask plate 2, the oscillation unit 7 applies vibration force to the mask plate 2, so as to cause residual material on the mask plate 2 to fall off. In order to achieve better cleaning effect, the device for cleaning mask plates further includes an electrostatic adsorption unit. The electrostatic adsorption unit generates static electricity to adsorb residual material on the mask plate 2. The electrostatic adsorption unit may cooperate with the oscillation unit 7, so as to cause the residual material on the mask plate 2 to fall off under the effect of both of the electrostatic force and the gravity, thereby further improving cleaning effect.

Specifically, the vapor deposition apparatus further includes a vapor deposition chamber 4, a substrate 1 which is provided with a back circuit, a fine metal mask (FMM) 2, a crucible 3. The substrate 1, the FMM 2 and the crucible 3 are arranged from top to bottom. The oscillation unit 7 may employ an ultrasonic oscillator. The ultrasonic oscillator may be provided at a lateral side of the mask plate 2. The electrode clamps 9 are clamped to four corners of the mask plate 2 and in electrical connection with the power supply 8. The recovery unit 6 is in electrical connection with the power supply 8, and is under the mask plate 2. The power supply 8 applies a voltage between the recovery unit 6 and the mask plate 2 to produce an electrostatic adsorption force. By adjusting vibration intensities of different ultrasonic oscillators, the residual material on the mask plate 2 may be removed with different priorities. Meanwhile, under the effect of both of the electrostatic adsorption force and the gravity, it is able to accelerate the speed at which the residual organic material falls off from the mask plate, thereby greatly improving cleaning effect. Other details have been described in the above, and will not be repeated here.

The present disclosure provides in some embodiments a method for cleaning mask plates, which includes following steps: after completion of vapor deposition with the mask plate 2, applying vibration force to the mask plate 2 by adjusting vibration intensities and frequencies of the oscillation units 7 to cause residual material on the mask plate 2 to fall off. The method for cleaning mask plates may clean a fine metal frame (FMM). The oscillation unit 7 may employ an ultrasonic oscillator. The ultrasonic oscillator may be provided at a lateral side of the mask plate 2. In one embodiment, each lateral side of the mask plate 2 is provided with one ultrasonic oscillator. By adjusting vibration intensities of different ultrasonic oscillators, the residual material on the mask plate 2 may be removed with different priorities. As can be seen, the ultrasonic oscillators provide vibration energy for the mask plate 2, and it is able to adjust the speed at which the organic material falls off from the mask plate by adjusting vibration intensities and frequencies of the ultrasonic oscillators. It should be noted, when adjusting the frequencies of the ultrasonic oscillators, it is needed to avoid the natural frequency of the mask plate 2, so as to prevent resonance which may damage the mask plate 2.

In addition, after completion of vapor deposition with the mask plate 2, the method further includes the following step: applying a voltage between the recovery unit 6 and the mask plate 2 through the electrostatic adsorption unit so as to produce an electrostatic adsorption force for adsorbing residual material on the mask plate 2. As a result, under the effect of both of the electrostatic adsorption force and the gravity, it is able to accelerate the speed at which the residual organic material falls off from the mask plate, and the residual organic material fallen off from the mask plate can be collected by the recovery unit 6 and reused, thereby greatly improving cleaning effect. Specifically, positive and negative voltages may be applied to the recovery unit 6 and the mask plate 2 through a multi-channel power supply 8 so as to produce an electrostatic adsorption force between the recovery unit 6 and the mask plate 2. The electrode clamps 9 may be clamped to corners of the mask plate 2, i.e., providing one electrode clamp at each of four corners of the mask plate 2, thereby avoiding voltage drop caused by load resistance of the mask plate and achieving voltage compensation. In addition, it is able to change electrostatic adsorption strengths of different regions with different priorities by adjusting sizes of electrode voltages.

In sum, as compared with the two methods in the related art, the method for cleaning mask plates of the present disclosure achieves cleaning of the organic light emitting material according to the ultrasonic vibration principle, and can effectively avoid the problems of damage of the mask plate, waste of resources and environment pollution in the methods of the related art such as cleaning with organic solvent or high temperature. In addition, by cleaning the mask plate through oscillating the mask plate, it is able to avoid introduction of external contamination, reuse recycled material, greatly save time and resource costs, and is suitable for green production and mass production.

The above are merely the preferred embodiments of the present disclosure. A person skilled in the art may make further modifications and improvements without departing from the principle/spirit of the present disclosure, and these modifications and improvements shall also fall within the scope of the present disclosure.

What is claimed is:

1. A device for cleaning a mask plate comprising:
an oscillation unit;
wherein the oscillation unit is on the mask plate; after completion of vapor deposition with the mask plate, the oscillation unit applies vibration force to the mask plate in a manner of causing residual material on the mask plate to fall off.

2. The device according to claim 1, further comprising an electrostatic adsorption unit; wherein the electrostatic adsorption unit generates static electricity to adsorb the residual material on the mask plate.

3. The device according to claim 2, further comprising a recovery unit; wherein the recovery unit is configured to collect residual material fallen off from the mask plate.

4. The device according to claim 3, wherein the electrostatic adsorption unit comprises a power supply and electrode clamps; the electrode clamps are clamped to the mask plate and in electrical connection with the power supply; the recovery unit is in electrical connection with the power supply; the power supply applies a voltage between the recovery unit and the mask plate to produce an electrostatic adsorption force.

5. The device according to claim 4, wherein the electrode clamps are clamped to corners of the mask plate, respectively.

6. The device according to claim 1, wherein the oscillation unit is an ultrasonic oscillator; the ultrasonic oscillator is at a lateral side of the mask plate.

7. The device according to claim 1, wherein the mask plate is a metal mask plate.

8. A vapor deposition apparatus comprising:
a mask plate; and
a device for cleaning the mask plate;
wherein the device comprises an oscillation unit on the mask plate.

9. The vapor deposition apparatus according to claim 8, wherein the oscillation unit comprises an ultrasonic oscillator.

10. The vapor deposition apparatus according to claim 9, wherein the ultrasonic oscillator is at a lateral side of the mask plate.

11. The vapor deposition apparatus according to claim 8, further comprising a vapor deposition chamber, a substrate with a back circuit and a crucible; wherein the substrate and the crucible are in the vapor deposition chamber, and the mask plate is between the substrate and the crucible.

12. The vapor deposition apparatus according to claim 8, further comprising an electrostatic adsorption unit; wherein the electrostatic adsorption unit faces evaporation membrane material deposited on the mask plate.

13. The vapor deposition apparatus according to claim 12, further comprising a recovery unit; wherein the recovery unit is in electrical connection with the electrostatic adsorption unit.

14. The vapor deposition apparatus according to claim 13, wherein the electrostatic adsorption unit comprises a power supply and electrode clamps; the electrode clamps are clamped to the mask plate and in electrical connection with the power supply; the recovery unit is in electrical connection with the power supply.

15. The vapor deposition apparatus according to claim 14, wherein the electrode clamps are clamped to corners of the mask plate.

16. A method for cleaning a mask plate, comprising:
after completion of vapor deposition with the mask plate, applying vibration force to the mask plate by adjusting vibration intensities and frequencies of oscillation units to cause residual material on the mask plate to fall off.

17. The method according to claim 16, wherein before, after or simultaneously with applying vibration force to the mask plate by adjusting vibration intensities and frequencies of the oscillation units, the method further comprises:
applying a voltage between a recovery unit and the mask plate through an electrostatic adsorption unit so as to produce an electrostatic adsorption force, to accelerate a speed at which the residual organic material falls off from the mask plate to the recovery unit under effect of the electrostatic adsorption force and the gravity.
